(19) United States
(12) Patent Application Publication
(10) Pub. No.: US 2014/0087074 A1
(43) Pub. Date: Mar. 27, 2014

(54) FILM FORMATION JIG AND FILM FORMATION METHOD USING THE SAME

(71) Applicant: FUJIFILM CORPORATION, Tokyo (JP)

(72) Inventor: Yasutoshi HIRABAYASHI, Kanagawa (JP)

(73) Assignee: FUJIFILM CORPORATION, Tokyo (JP)

(21) Appl. No.: 14/037,113

(22) Filed: Sep. 25, 2013

(30) Foreign Application Priority Data
Sep. 27, 2012 (JP) 2012-214283

(51) Int. Cl. C23C 16/458

(52) U.S. Cl. CPC C23C 16/458
USPC 427/248.1; 118/500

(57) ABSTRACT

A film formation jig is configured to be used in a film formation process to a device constituted of members having heat-resistant temperatures different from each other, in which a film is formed on a film formation target member of the device having a heat-resistant temperature higher than a heat-resistant temperature of a non-film formation portion of the device. The film formation jig includes: a retaining member configured to retain the device, the retaining member having a part which is configured to come into contact with a surface of the film formation target member of the device and is shaped in accordance with the surface of the film formation target member; and a mask member configured to mask the non-film formation portion of the device. The retaining member and the mask member have projections disposed on parts configured to come into contact with the non-film formation portion of the device.

### BACKGROUND OF THE INVENTION

1. Field of the Invention

The present invention relates to a film formation jig and a film formation method using the film formation jig, and more particularly to a film formation jig to be used in a film formation process to form a film on a film formation target object, which is constituted of a plurality of members having heat-resistant temperatures different from each other, and a film formation method using the film formation jig.

2. Description of the Related Art

In a case where a film formation process is performed with respect to a device constituted of a plurality of materials having heat-resistant temperatures different from each other, it is necessary to set a film formation temperature in accordance with a lower one of the heat-resistant temperatures of the materials, such as flexible printed circuits (FPC), even if a film is formed on a part with a higher one of the heat-resistant temperatures. Further, degassing from the material and the like, if occurring, may cause contamination in the film formation process. It is necessary, therefore, to perform the film formation process at a temperature lower than the temperature at which the degassing occurs. In a case where the film formation process involves use of gas in particular, such as a chemical vapor deposition (CVD) method, the influence of degassing is notable. Accordingly, it is difficult to form a film of a material that essentially requires high film formation temperature to have sufficient performance, on a device constituted of a material having low heat-resistant temperature.

For example, Japanese Patent Application Publication No. 2012-015163 describes a photo-assisted CVD apparatus in which, in order to reduce adhesion of a film formation material to a mask pattern, a mask body includes a heating coil for keeping the mask body at a temperature (100° C.) that suppresses adhesion of the film formation gas. Japanese Patent Application Publication No. 2012-082504 describes a heat-treatment apparatus including an anode electrode provided with a heater and a cooling tube which is arranged along the heater so as to keep the temperature of a processed material uniform. This makes it possible to provide a difference in temperature in a specified region.

Further, Japanese Patent Application Publication No. 08-288286 describes a film formation method at partially varied temperatures by irradiating a part of the surface of a substrate with a laser beam, strong light or an energy beam. A heating method involving passing of induced current is also described therein.

As described above, in Japanese Patent Application Publication Nos. 2012-015163, 2012-082504 and 08-288286, the methods for controlling temperature of the substrate or the mask are described. By using these methods, a film formation target can selectively be heated, so that a film can be formed on the film formation target at a temperature higher than a low heat-resistant temperature of a non-film formation target. In all of these methods, however, the temperature control is performed by supplying heat or supplying a cooling medium from the outside. In these cases, the configurations of the apparatuses are disadvantageously complicated and costs are increased. Furthermore, in Japanese Patent Application Publication No. 08-288286, the film formation is performed by using the laser beam so that the film with a fine pattern can be formed; however, patterning on a large area similarly requires the apparatus of extremely complicated configuration. In the case of heating with electric current, only heating can be performed, so that heat transmitted by heat conduction makes it difficult to control temperature.

### SUMMARY OF THE INVENTION

The present invention has been contrived in view of these circumstances, an object thereof being to provide a film formation jig and a film formation method using the film formation jig, capable of selectively heating a film formation target with a simple method so that a film can be formed on the film formation target at a temperature higher than a low heat-resistant temperature of a non-film formation target.

In order to attain the aforementioned object, the present invention is directed to a film formation jig configured to be used in a film formation process to a device constituted of a plurality of members having heat-resistant temperatures different from each other, wherein a film is formed on a film formation target member of the device having a heat-resistant temperature higher than a heat-resistant temperature of a non-film formation portion of the device, the film formation jig comprising: a retaining member configured to retain the device, the retaining member having a part which is configured to come into contact with a surface of the film formation target member of the device and is shaped in accordance with the surface of the film formation target member; and a mask member configured to mask the non-film formation portion of the device, wherein the retaining member and the mask member have projections disposed on parts configured to come into contact with the non-film formation portion of the device.

According to this aspect of the present invention, in forming a film on the film formation target member, which has a high heat-resistant temperature, of the device constituted of the plurality of members having the heat-resistant temperatures different from each other, the retaining member has the part shaped in accordance with the surface of the film formation target member where the film formation is performed, so that the contact area of the film formation target member can be increased. Therefore, it becomes possible to easily transmit heat from the retaining member to the film formation target member by heat conduction, so that the temperature of the film formation target member can be made high. On the contrary, since the non-film formation portion of the device is brought into contact with the projections of the retaining member and the mask member, the contact area of the non-film formation portion with the retaining member and the mask member can be reduced. Therefore, heat conduction to the non-film formation portion from the retaining member and the mask member can be suppressed.

In the case where a film formation process is performed with respect to a device including an organic substance, high temperature causes generation of a large amount of gas such as phthalate-based gas and hydrocarbon-based gas, and the generated gas that is taken into an interface between the formed film and the film formation target member or taken into the formed film, hinders provision of sufficient performance. Therefore, it is necessary to perform the film formation process at low temperature. In the present specification, in the case where a film formation process is performed with respect to a device including an organic substance, “heat-resistant temperature” refers to a threshold temperature, a temperature over the threshold temperature disabling a film formation object from obtaining sufficient performance due to an influence of degassing, whereas in other cases, “heat-resistant temperature” refers to a threshold temperature, a temperature over the threshold temperature deteriorating the material and preventing provision of sufficient performance.

Preferably, a contact area of the non-film formation portion of the device with the projections of the retaining member and the mask member is not larger than 1% of an area of the non-film formation portion.

According to this aspect of the present invention, the contact area of the non-film formation portion with the projections of the retaining member and the mask member is 1% or less, so that heat conduction from the retaining member and the mask member to the non-film formation portion can be suppressed, and thereby temperature increase in the non-film formation portion can be suppressed.

Preferably, the film formation jig is configured to be used in the film formation process at a film formation temperature of not higher than 250° C.

When the film formation jig is used in the film formation process at a film formation temperature of 250° C. or lower, a film is formed on conditions with less influence of heat transfer by thermal radiation. Therefore, since heat transfer to the non-film formation member is dominantly implemented by heat transmission from contact points with the projections of the retaining member and the mask member, the heat transfer to the non-film formation member can be suppressed.

Preferably, the film formation jig is configured to be used in the film formation process by a CVD method.

According to this aspect of the present invention, since the film formation jig can prevent occurrence of degassing from the non-film formation portion, even when the jig is used in the film formation process by the CVD method, an amount of organic contamination components mixed in the film formation gas can be lessened. Therefore, the jig can preferably be used in the film formation process by the CVD method.

Preferably, the film formation jig is configured to be used in the film formation process under reduced pressure.

According to this aspect of the present invention, since the film formation jig is used in the film formation process under reduced pressure, the gas serving as a medium of heat transfer can be lessened. Accordingly, a heat insulation effect can be enhanced and heat transfer by heat transmission can be suppressed, as a result of which temperature increase in the device is dominantly caused by heat conduction from the film formation jig. Therefore, the temperature of the film formation target member can be increased while the temperature increase in the non-film formation portion can be suppressed. This makes it becomes possible to suppress temperature increase in the non-film formation portion itself even when the film formation target member and the non-film formation portion have different heat-resistant temperatures, and the film formation temperature can be higher than the heat-resistant temperature of the non-film formation portion.

Preferably, a surface of the mask member is configured to be flush with a film formation surface of the film formation target member of the device.

According to this aspect of the present invention, the film formation surface can be set to be flush with the mask member, so that in the film formation process with use of plasma, discharge due to electric field concentration can be prevented and thereby a uniform film can be formed.

Preferably, the mask member is made of at least one of titanium and chromium.

According to this aspect of the present invention, forming the mask member from titanium or chromium makes it possible to enhance adhesiveness with adhering substances at the film formation process. This makes it possible to prevent the adhering substances from being detached during the film formation process.

It is also preferable that the mask member is made of at least one of titanium and chromium.

According to this aspect of the present invention, the mask member is made of ceramics, so that durability of the mask member can be maintained even when the adhering substances are removed by wet etching or dry etching for reuse of the mask member.

Preferably, the film formation jig is configured to be used in the film formation process to an inkjet head.

In order to attain the aforementioned object, the present invention is also directed to a film formation method of forming a film using the above-described film formation jig, the method comprising: retaining the device with the film formation jig; and applying heat to the film formation target member of the device from a side of the retaining member under reduced pressure to form a film on the film formation target member.

According to this aspect of the present invention, a film is formed under reduced pressure so that heat transmission by the atmosphere is suppressed, and using the film formation jig makes it possible to use heat conduction to heat the film formation target member since the film formation target member has a large contact area while suppressing heating of the non-film formation portion since the non-film formation portion has a small contact area. Accordingly, since only the film formation target member can selectively be heated, the film can be formed on the film formation target member at a temperature higher than the low heat-resistant temperature of the non-film formation portion. Therefore, the film can be formed at high temperature even on the device constituted of a material having low heat-resistant temperature and previously failed to have a film formed thereon at high temperature. This makes it possible to implement the film formation process on conditions suitable for each film formation target member.

According to the film formation jig and the film formation method using the film formation jig of the present invention, a film formation portion can selectively be heated. Accordingly, even when a film is formed on a device including a non-film formation portion with low heat-resistant temperature, the film can be formed on a film formation portion at a temperature higher than the heat-resistant temperature of the non-film formation portion.

### BRIEF DESCRIPTION OF THE DRAWINGS

The nature of this invention, as well as other objects and advantages thereof, will be explained in the following with reference to the accompanying drawings, in which like reference characters designate the same or similar parts throughout the figures and wherein:

FIG. 1 is a perspective view of an inkjet head;

FIG. 2 is a perspective view showing a film formation jig mounted on an inkjet head module;

FIG. 3 is a cross sectional view of the film formation jig shown in FIG. 2; and

FIG. 4 is a schematic view of a CVD apparatus.

### DETAILED DESCRIPTION OF THE PREFERRED EMBODIMENTS

Hereinafter, a description is given of a film formation jig and a film formation method using the film formation jig according to embodiments of the present invention with reference to the accompanying drawings. An inkjet head device formed by connecting a flexible printed circuit (FPC) for driving to a structure member made of silicon (Si) is described hereinafter as a film formation target object; however, the present invention is not limited thereto but is applicable to any film formation target object constituted of at least two members having heat-resistant temperatures different from each other.

### <Configuration of Inkjet Head>

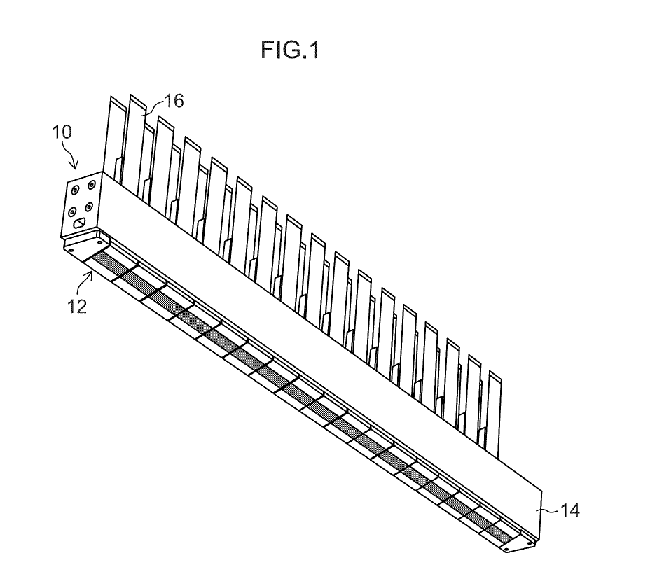

First, the configuration of an inkjet head is described. FIG. 1 is a perspective view of the inkjet head 10, in which an ejection face of the inkjet head 10 is depicted from a lower side (diagonally downward side). The inkjet head 10 is a print head to be mounted in an image formation unit of an inkjet recording apparatus, and is a full line type bar head (single pass printing type page-wide head) lengthened by arraying and connecting a plurality of head modules 12 in a paper widthwise direction. Although the inkjet head 10 shown in FIG. 1 is constituted of seventeen head modules 12 arranged in a line, a module configuration, the number of modules and an array form thereof are not limited to the illustrated example. The head modules 12 are fixed to a frame or housing 14 (housing for structuring the bar shaped line head), and are connected with flexible printed circuits (FPC) 16.

Hereinafter, a description is given of a film formation method of forming a film on a nozzle face of each of the head modules 12 with a film formation jig according to the present embodiment. The film formation method can be performed, for example, to form a film of SiO₂ on the nozzle face as a ground of a water-repellent film to be subsequently formed. The film formation method can also be performed to form a film of amorphous-silicon, poly-silicon, SiOC, or the like. A structure member of the head module 12 that has ink passages and is made of Si is hereinafter referred to as an Si device 18.

The film formation process on the nozzle face of the head module 12 is preferably carried out in a state where the flexible printed circuit 16 has been connected to the head module 12. If connection of the flexible printed circuit 16 and other processing are performed after the film is formed on the nozzle face, clogging of nozzles can be caused by dust generated during the processing, and the film formed on the nozzle face can peel off. Therefore, it is preferable that the film formation process on the nozzle face is performed in the final stage of manufacturing process of the head module 12.

### Film Formation Jig

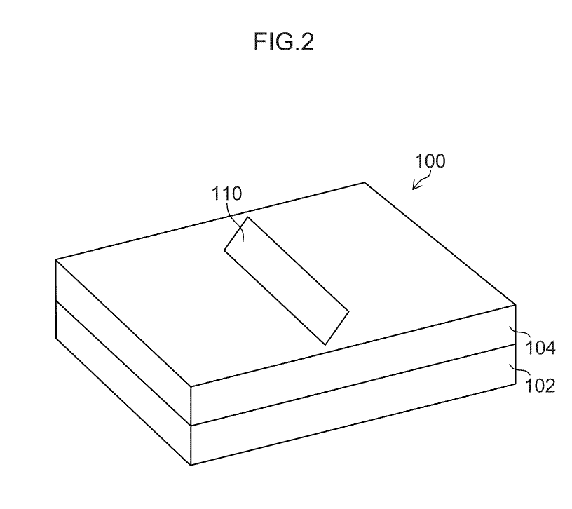

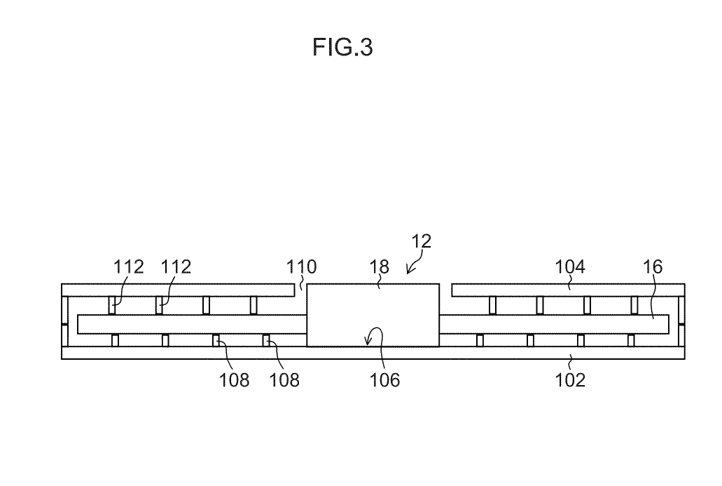

FIG. 2 is a perspective view showing a film formation jig 100 mounted on the head module 12 that is a film formation target object, and FIG. 3 is a cross sectional view of FIG. 2. The film formation jig 100 includes a retaining member 102 and a mask member 104.

The retaining member 102 is configured to retain the head module 12, and the mask member 104 is configured to mask a non-film formation portion of the head module 12. In the film formation process, the film formation jig 100 is used so as to interpose the head module 12 that is the film formation target object between the retaining member 102 and the mask member 104.

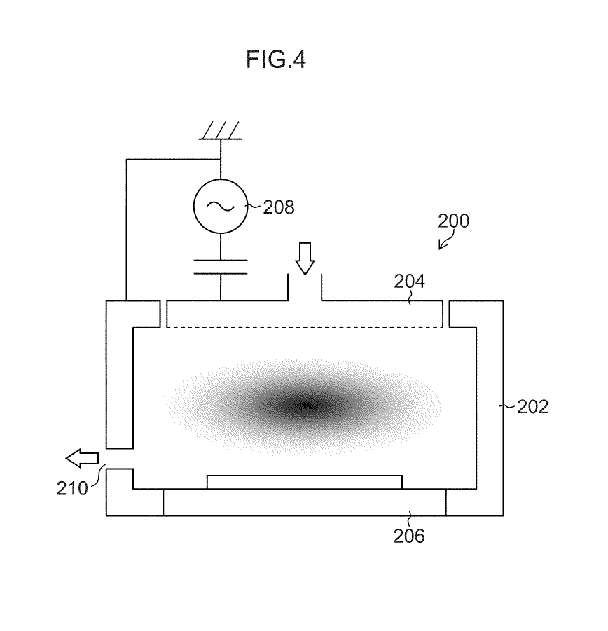

The retaining member 102 has a contact surface 106, which comes into contact with the Si device 18 that is the film formation target member of the head module 12. The contact surface 106 is configured so as to increase a contact area with the Si device 18, and it is possible to conduct heat of the retaining member 102 to the Si device 18, and to thereby set the Si device 18 at high temperature. As described later, the temperature of the retaining member 102 becomes high as it comes into contact with a lower electrode 206 of a CVD apparatus 200 (see FIG. 4). Therefore, a film formation temperature of the Si device 18 where film formation is desirably performed at high temperature can be increased by making the Si device 18 in contact with the retaining member 102.

The retaining member 102 has projections 108, each of which has a protruding shape and is arranged in a part to come into contact with the non-film formation portion (the flexible printed circuit 16) of the head module 12, so that the retaining member 102 is in point contact with the non-film formation portion through the projections 108. Since it is not necessary to form the film on the non-film formation portion, the temperature of the non-film formation portion is not needed to be increased. Moreover, in the present embodiment, since the non-film formation portion is the flexible printed circuit 16 having a low heat-resistant temperature, it is undesirable to allow the temperature of the flexible printed circuit 16 to become high. By bringing the retaining member 102 into contact with the flexible printed circuit 16 through the projections 108, heating of the flexible printed circuit 16 with the heat conducted from the retaining member 102 can be prevented. Therefore, it is possible to prevent the temperature of the flexible printed circuit 16 from becoming high. When a flexible printed circuit is used as a non-film formation member, it is necessary to keep the temperature low during the film formation process since the flexible printed circuit has a heat-resisting property lower than that of the Si device. It is preferable that the contact area of the flexible printed circuit 16 with the projections 108 of the retaining member 102 is 1% or less of the area of the portion of the flexible printed circuit 16 that is covered with the retaining member 102 and the mask member 104, and it is more preferable to make the contact area of the flexible printed circuit 16 with the projections 108 smaller within the range where the flexible printed circuit 16 can be retained.

Contrary to this, it is preferable to increase the contact area of the Si device 18 with the contact surface 106 of the retaining member 102. Since the Si device 18 is the film formation target member, the temperature of the Si device 18 needs to be increased. Therefore, in order to increase the contact area of the Si device 18 with the contact surface 106 of the retaining member 102 so that heating of the Si device 18 can be performed by heat conduction from the retaining member 102, it is preferable that the contact surface 106 is shaped in accordance with the surface of the Si device 18, and the Si device 18 is supported by surface contact with the contact surface 106.

The mask member 104 is a protection member so as to prevent the film from being formed on portions other than the film formation target member of the film formation target object. The mask member 104 has an opening 110 in a portion corresponding to the Si device 18 and covers the non-film formation portion of the head module 12 so as to allow the film to be formed only on the film formation target member. Similarly to the retaining member 102, the mask member 104 has projections 112, each of which has a protruding shape and is arranged in a part to come into contact with the non-film formation portion of the head module 12, so that the mask member 104 is in point contact with the non-film formation portion through the projections 112. Also in the mask member 104, the flexible printed circuit 16 is brought into contact with the projections 112, which makes it possible to prevent the flexible printed circuit 16 from being heated by the heat conducted from the mask member 104. As in the case of the retaining member 102, it is preferable that the contact area of the flexible printed circuit 16 with the projections 112 of the mask member 104 is 1% or less of the area of the portion of the flexible printed circuit 16 that is covered with the retaining member 102 and the mask member 104, and it is more preferable to make the contact area of the flexible printed circuit 16 with the projections 112 smaller within the range where the flexible printed circuit 16 can be retained.

It is necessary for the material of the retaining member 102 to have the heat-resistant temperature that is higher than the film formation temperature, and the material can be SUS 303, for example. It is also necessary for the material of the mask member 104 to have the heat-resistant temperature that is higher than the film formation temperature. Moreover, it is preferable that the material of the mask member 104 has sufficient adhesiveness with respect to the film formation material. Since the mask member 104 is mounted on the film formation side of the film formation target object, the film formation material can be deposited onto the surface of the mask member 104. If the adhesiveness between the film formation material and the mask member 104 is poor, the film formation material deposited on the mask member 104 can peel off the mask member 104 and contaminate the inside of the film formation apparatus. The material of the mask member 104 can be titanium (Ti), chromium (Cr), or the like. Moreover, blast processing (removal of oxides and foreign substances) can be performed on the materials of the mask member 104 and the retaining member 102. In the case of reusing the mask member 104, it is preferable to remove the material deposited on the mask member 104. Durability of the mask member 104 in reuse can be enhanced by manufacturing the mask member 104 with such materials as ceramics which have resistance in wet etching, dry etching and the like.

The projections 108 of the retaining member 102 and the projections 112 of the mask member 104 can be produced by such methods as machining, etching, and press fitting of pins.

Further, it is preferable that the upper surface that is the film formation target portion of the Si device 18 is flush with the upper surface of the mask member 104, as shown in FIG. 3. By making the upper surface of the mask member 104 flush with the upper surface of the film formation target portion of the film formation target object, discharge due to electric field concentration can be prevented in the film formation process with use of plasma. To be “flush” hereby means that the difference in height between the upper surface of the film formation target member and the upper surface of the mask member is not larger than 1 mm.

### Film Formation Method

A description is now given of a film formation method using the film formation jig 100. The film formation method can be performed as follows, for example.

FIG. 4 is a schematic view showing an embodiment of the CVD apparatus. The CVD apparatus 200 shown in FIG. 4 is a parallel plate-type plasma enhanced CVD apparatus, which has a chamber 202 inside the apparatus. An upper electrode (cathode) 204 is arranged at an upper part of the chamber 202, and a lower electrode (anode) 206 is arranged at a lower part of the chamber 202. The upper electrode 204 is connected to a high frequency power supply (RF power supply) 208 for plasma generation. The frequency of the RF power supply 208 can be not lower than 13.56 MHz and not higher than 60 MHz, and can be 13.56 MHz, for example.

The upper electrode 204 has a plurality of apertures through which a process gas is supplied into the chamber 202. The lower electrode 206 is provided with a heater that heats a film formation target object placed on the lower electrode 206. The chamber 202 has an exhaust port 210 to adjust pressure inside the chamber 202. The exhaust port 210 is connected to a vacuum pump (not shown) so as to adjust the pressure inside the chamber 202.

As a sample, the head module 12 including the flexible printed circuit 16 in the state of being retained in the above-described film formation jig 100 is placed on the lower electrode 206 of the CVD apparatus 200. When the film formation jig 100 is placed on the lower electrode 206, the retaining member 102 of the film formation jig 100 is heated with the heater in the lower electrode 206, and the temperature of the Si device 18 in contact with the retaining member 102 can be thereby increased.

The temperature of the heater as the film formation temperature is set at 200° C., the film formation pressure is set at 20 Pa, and there is used a gas prepared by mixing TEOS (tetraethoxysilane: Si(OC₂H₅)₄) with Ar as carrier gas at a specified ratio. The ratio of TEOS to Ar can properly be determined on the basis of a film formation rate, surface uniformity, and the like. Film formation power is set at 150 W, and film formation time is set at 10 minutes (where the duration from placement of the sample on the heater to extraction of the sample is 30 minutes).

The film formation method is not limited to the aforementioned plasma CVD method, and low-temperature CVD methods such as a photo-assisted CVD method and a Cat-CVD (catalytic chemical vapor deposition) method, and PVD (physical vapor deposition) methods such as a vapor deposition method and a sputtering method are also applicable. The film formation material is also not particularly limited, and materials such as metal and semiconductors can be used in addition to the above-described SiO₂.

The film formation pressure is also not particularly limited; however, a lower film formation pressure is preferable because the heat insulation effect is enhanced with the amount of gas that serves as a medium of heat transfer being smaller. The film formation pressure is preferably lower than normal pressure, and is preferably not higher than 100 Pa.

The film formation time is preferably as short as possible so as to prevent heat transmission from the heater to the flexible printed circuit. It is preferable to shorten the film formation time by conveying the sample through a load lock chamber into the chamber 202 in which a vacuum state is produced in advance.

It is preferable that the film formation temperature is not higher than 250° C. The heat transfer can be divided into heat conduction, heat transmission, and heat radiation. The heat radiation can be expressed as follows:

q/A=σ·(T₁⁴−T₂⁴),

where q is the heat-transfer amount (W), A is the heat-transfer surface area (m²), σ is the Stephen Boltzmann's factor (W/m²/K⁴), T₁ is the temperature of high-temperature object (K), and T₂ is the temperature of low-temperature object (K).

The heat radiation is proportional to the 4th power of the temperature, and the ratio becomes larger as the temperature becomes higher. By limiting the film formation temperature to 250° C. or lower, an influence of the radiant heat can be reduced. Further, in the case where gas is generated by heating the non-film formation portion, it is necessary to keep the temperature of the non-film formation portion lower than the temperature at which the gas is substantially generated. By using the film formation jig according the present embodiment, the temperature of the non-film formation portion can be kept low so that generation of gas is prevented, while securing the desirable film formation temperature.

Further, by performing the film formation process in the reduced pressure state, the heat transfer by the atmosphere becomes less likely to occur. Therefore, the heat transfer to the flexible printed circuit 16 is dominantly performed by the heat transmission through the contact points with the film formation jig 100. More specifically, when the film formation temperature is 250° C. or lower, the amount of heat transfer to the flexible printed circuit 16 can be reduced by decreasing the contact points between the film formation jig 100 and the flexible printed circuit 16.

### Other Embodiments

Although the film is formed on the head module 12 having the flexible printed circuit 16 in the above-described embodiment, the present invention can also be used when a film of poly-silicon, amorphous-silicon, Si₃N₄ or other materials is formed in manufacturing of thin-film transistor (TFT) elements in liquid crystal displays and thin-film silicon solar batteries, for example.

### Examples

In Example 1, the film formation jig 100 of the present embodiment was used to form a film on the head module 12 including the flexible printed circuit 16 with the above-described CVD apparatus 200 under the above-described conditions. In Comparative Example 1, the head module 12 was directly placed on the lower electrode 206 and a film was formed without using the film formation jig. In Comparative Example 2, a jig similar to the film formation jig 100 but having no projections on a member for retaining the non-film formation portion was prepared, and the head module 12 was contained in the jig so that the flexible printed circuit 16 was directly retained on the surface of the retaining member to carry out the film formation process. A polyimide film was used as the material of the flexible printed circuit 16 in each example.

In Comparative Example 1, discharge was generated by plasma, so that the flexible printed circuit was burned and an electric short circuit occurred, which made the use of the inkjet head impossible. In Comparative Example 2, no discharge caused by plasma was observed, and external appearance and performance of the flexible printed circuit after the film formation process were sufficient. However, since heat was transmitted from the jig to the flexible printed circuit and degassing from the flexible printed circuit occurred, organic contamination was observed on the formed film. In Example 1, external appearance and performance of the flexible printed circuit after the film formation process were sufficient, and no contamination of organic substances was observed on the formed film, which indicated that the film formation process was successfully conducted.

The organic contamination was analyzed by the following method. In-depth analysis of time-of-flight secondary ion mass spectrometry (ToF-SIMS) was conducted by using a formed SiO₂ film as follows:
Device: TOF. SIMS5 (made by ION-TOF GmbH)
Primary ion source: Bi
Measurement mode: high mass resolution
Measurement surface: a 30 μm square
Cation analysis

As a result of analyzing components of the formed film, C₄H₉ and C₅H₁₁ attributed to straight chain hydrocarbon, and C₈H_{S}O₃ attributed to phthalic acid were detected as organic contamination in Comparative Example 2. In Eample 1, contamination of organic substances was not detected.

It should be understood that there is no intention to limit the invention to the specific forms disclosed, but on the contrary, the invention is to cover all modifications, alternate constructions and equivalents falling within the spirit and scope of the invention as expressed in the appended claims.

What is claimed is:

1. A film formation jig configured to be used in a film formation process to a device constituted of a plurality of members having heat-resistant temperatures different from each other, wherein a film is formed on a film formation target member of the device having a heat-resistant temperature higher than a heat-resistant temperature of a non-film formation portion of the device, the film formation jig comprising:
a retaining member configured to retain the device, the retaining member having a part which is configured to come into contact with a surface of the film formation target member of the device and is shaped in accordance with the surface of the film formation target member; and
a mask member configured to mask the non-film formation portion of the device,
wherein the retaining member and the mask member have projections disposed on parts configured to come into contact with the non-film formation portion of the device.

2. The film formation jig as defined in claim 1, wherein a contact area of the non-film formation portion of the device with the projections of the retaining member and the mask member is not larger than 1% of an area of the non-film formation portion.

3. The film formation jig as defined in claim 1, wherein the film formation jig is configured to be used in the film formation process at a film formation temperature of not higher than 250° C.

4. The film formation jig as defined in claim 1, wherein the film formation jig is configured to be used in the film formation process by a CVD method.

5. The film formation jig as defined in claim 1, wherein the film formation jig is configured to be used in the film formation process under reduced pressure.

6. The film formation jig as defined in claim 1, wherein a surface of the mask member is configured to be flush with a film formation surface of the film formation target member of the device.

7. The film formation jig as defined in claim 1, wherein the mask member is made of at least one of titanium and chromium.

8. The film formation jig as defined in claim 1, wherein the mask member is made of ceramics.

9. The film formation jig as defined in claim 1, wherein the film formation jig is configured to be used in the film formation process to an inkjet head.

10. A film formation method of forming a film using the film formation jig as defined in claim 1, the method comprising:
retaining the device with the film formation jig; and
applying heat to the film formation target member of the device from a side of the retaining member under reduced pressure to form a film on the film formation target member.
